(19) United States
(12) Patent Application Publication
(10) Pub. No.: US 2008/0105914 A1
(43) Pub. Date: May 8, 2008

(54) TITANIUM OXIDE EXTENDED GATE FIELD EFFECT TRANSISTOR

(75) Inventors: Jung-Chuan Chou, Yunlin County (TW); Hung-Hsi Yang, Taoyuan County (TW)

Correspondence Address: QUINTERO LAW OFFICE, PC, 2210 MAIN STREET, SUITE 200, SANTA MONICA, CA, 90405, US

(73) Assignee: NATIONAL YUNLIN UNIVERSITY OF SCIENCE AND TECHNOLOGY, YUNLIN (TW)

(21) Appl. No.: 12/013,299

(22) Filed: Jan. 11, 2008

Related U.S. Application Data
(62) Division of application No. 11/384,918, filed on Mar. 20, 2006.

(30) Foreign Application Priority Data
Apr. 4, 2005 (TW) TW94110721

(51) Int. Cl. H01L 29/94

(52) U.S. Cl. 257/310; 257/E29.345

(57) ABSTRACT

A titanium oxide extended gate field effect transistor (EGFET) device and fabricating method thereof. Titanium oxide is formed on an EGFET by sputtering, coating a detection membrane therefor. Current-voltage relationships at different pH values are also measured via a current measuring system. Sensitivity parameter of the titanium oxide EGFET is calculated according to a relationship between a pH value and a gate voltage.

### BACKGROUND OF THE INVENTION

1. Field of the Invention

The invention relates to an extended gate field effect transistor (EGFET) and, in particular, to a titanium oxide extended gate field effect transistor (EGFET) and a fabricating method thereof.

2. Description of the Related Art

FIG. 1 is a schematic diagram of a conventional ion sensitive field effect transistor (ISFET). The conventional ISFET comprises a P-type silicon substrate 8, a gate structure, and N-type source/drain regions 7. The gate structure is formed on the P-type silicon substrate 8. The gate structure comprises a silicon dioxide (SiO₂) film 6 and a detection membrane 4 thereon. In the field effect transistor, the detection membrane 4 is the only element which directly contacts a solution 2. The other components of the field effect transistor are covered with an isolation region 3 made of epoxy. The source/drain regions 7 are formed adjacent to the silicon dioxide (SiO₂) film 6. The ISFET is connected to surroundings thereof via conducting wires 5 and 9, such as aluminum wires. When the detection membrane 4 is immersed in the solution 2, electrical signals are transmitted from the source/drain regions 7. In addition, the structure requires a reference electrode 1 to provide a stable voltage such that noise disturbance is minimized.

Disclosures relating to the formation of the ISFET or measurements thereof are detailed as follows.

In U.S. Pat. No. 5,350,701, Nicole Jaffrezic-Renault, Chovelon Jean-Marc, Hubert Perrot, Pierre Le Perchec, and Yves Chevalier on Sep. 27, 1994, a process is disclosed for producing a surface gate comprising a selective membrane for an integrated chemical sensor comprising a field effect transistor. The surface gate is particularly sensitive to the alkaline-earth species, and more particularly, to the calcium ion. The process comprises forming grafts on the surface gate.

In U.S. Pat. No. 5,387,328, Byung-ki Sohn on Feb. 7, 1995, a bio-sensor employing an ion sensitive field effect transistor (ISFET) is disclosed comprising a source and a drain formed in a substrate, and an ion sensitive gate placed between the source and drain. An ion sensitive film is formed on the ion sensitive gate and an immobilized enzyme membrane is defined on the ion sensitive film. A Pt electrode is formed on the ion sensitive film. The sensor has a Pt electrode capable of sensing all biological substances which generate H₂O₂ in enzyme reaction and high sensitivity and rapid reaction time can thus be achieved.

In U.S. Pat. No. 5,309,085, Byung Ki Sohn on May 3, 1994, a measuring circuit is disclosed with a biosensor utilizing ion sensitive field effect transistors integrated on a single chip. The measuring circuit comprises two ion sensitive FET input devices composed of an enzyme FET having an enzyme sensitive membrane on the gate, a reference FET, and a differential amplifier for amplifying output signals of the enzyme FET and the reference FET.

In U.S. Patent No. 20040067646, Nongjian Tao, Salah Boussaad on Apr. 8, 2004, a method is disclosed for forming atomic-scale contacts and an atomic-scale bandgap between two electrodes. The method comprises applying a voltage between two electrodes in a circuit with a resistor. The applied voltage etches metal ions off one electrode and deposits the metal ions onto the second electrode. The metal ions are deposited on the sharpest point of the second electrode, causing the second electrode to grow toward the first electrode until an atomic-scale contact is formed. Due to increasing resistance of the resistor, etching and deposition stop at the formed contact, forming an atomic-scale gap. The atomic-scale contacts and bandgaps formed according to this method are useful as a variety of nanosensors including chemical sensors, biosensors, hydrogen ion sensors, heavy metal ion sensors, magnetoresistive sensors, and molecular switches.

In U.S. Pat. No. 4,699,511, George A. Seaver on Oct. 13, 1987, a sensor of an index of refraction is disclosed utilizing a sensor face inclined at the nominal critical angle of an incident beam. The sensor surface refracts or reflects this incident radiation depending on the wavelength and the index of refraction thereof. The sensing apparatus of refraction includes a broadband radiant energy source, a radiant energy guide and collimating means. A prism sensing element is interposed in the radiant energy guide. A detector continuously detects the spectral intensities of the broadband radiant energy reflected by the prism sensing element. A single mode optical fiber is used as the radiant energy guide and collimating means for directing the broadband radiant energy to the prism and a multimode optical fiber returns the reflected radiant energy to the detector. The prism sensing element is formed with a suitable transparent material, such as silica, dense flint glass, or titanium dioxide depending upon the desired optical dispersion and sensitivity. Additionally, an end of the single mode optical fiber can be polished to act as the prism sensing element, with a mirror face reflecting beams at a particular angle. The single mode fiber can also act as a guiding means for signals from the detector.

In U.S. Patent No. 20030054177, Ping Jin on Mar. 20, 2003, multifunctional high-performance automatic chromogenic window coating material is disclosed. A vanadium dioxide based thermochromic material is coated by sputtering or the like onto a transparent substrate such as window glass. Titanium dioxide based photocatalytic material is coated on an outermost layer to act as antireflection film.

In U.S. Pat. No. 5,414,284, Ronald D. Baxter, James G. Connery, John D. Fogel, and Spencer V. Silverthorne on May 9, 1995, a method of forming ISFET devices and electrostatic discharge (ESD) protection circuits on the same substrate is disclosed. According to one aspect of the disclosure, an ESD protection circuit, comprising conventional protection devices, is integrated onto the same silicon chip where the ISFET is formed, along with an interface in contact with the liquid under measurement. There is no path of DC leakage current between the ISFET and the liquid. According to a preferred embodiment of the disclosure, a capacitor is used as an interface between the protection circuit and the liquid sample.

In U.S. Pat. No. 4,691,167, Hendrik H. v.d. Vlekkert, Nicolaas F. de Rooy on Sep. 1, 1987, an apparatus determining the reactivity of an ion in a liquid is disclosed. The system comprises a measuring circuit, an ion sensitive field effect transistor (ISFET), a reference electrode, a temperature sensor, amplifiers, a controller, computing circuits, and a memory. The sensing apparatus measures temperature and/or changes in the drain-source current, I_{D}, a function of temperature and controlled by a gate to source voltage difference V_{GS} such that the sensitivity can be calculated from a formula and stored in the memory.

In U.S. Pat. No. 4,660,063, Thomas R. Anthony on Apr. 21, 1987, a two-step process is disclosed utilizing laser drilling and solid-state diffusion to form a three-dimensional diode array in a semiconductor wafer. Holes are first formed in the wafer in various arrays by laser drilling, invoking little or no damage to the wafer under suitable conditions. Cylindrical P-N junctions are then formed around the laser-drilled holes by diffusing an impurity into the wafer from the walls of the holes. A variety of distinctly different ISFET devices are thus formed.

In U.S. Pat. No. 5,130,265, Massimo Battilotti, Giuseppina Mazzamurro, and Matteo Giongo on Jul. 14, 1992, a process is disclosed for obtaining a multifunctional ion-selective-membrane sensor. The process comprises preparation of a siloxanic prepolymer on an ISFET device, preparation of a solution of the siloxanic prepolymer, photochemical treatment in the presence of a photonitiator by means of UV light, chemical washing of the sensor with an organic solvent, and thermal treatment to complete the reactions of the polymerization.

Many materials, such as Al₂O₃, Si₃N₄, Ta₂O₅, a-WO₃, a-Si:H and others, can be used in detection membranes of ISFETs. The detection membranes are deposited by either sputtering or plasma enhanced chemical vapor deposition (PECVD), and the cost of thin film fabrication is higher. For commercial purposes, it is critical to develop a thin film with low cost and ease of fabrication. The ISFET differs from the EGFET only in that thin films of the ISFET are insulating membranes. However, in the EGFET, insulating membranes are replaced by conductive films.

An extended gate field effect transistor (EGFET) is evolved from an ion sensitive field effect transistor (ISFET). The extended gate field effect transistor (EGFET) has the advantages of low cost, simple structure, and ease of fabrication. The

An EGFET has advantages over an ISFET. The EGFET can be fabricated with MOSFETs formed by a CMOS standard process. In 1983, I. Lauks, J. Van Der Spiegel, P. Chan, D. Babic integrated the MOSFETs of the EGFET with readout circuits in one chip using CMOS standard process. Sensitivity of an IrO₂ membrane is measured.

### BRIEF SUMMARY OF THE INVENTION

The invention provides an extended gate field effect transistor with titanium oxide thin film formed by reactive sputtering. Titanium oxide thin films formed by sputtering have advantages such as sputtering with an insulating material, sputtering at a low pressure, uniform deposition in wide area, and so on.

The invention provides a method of measuring curves of drain current versus gate voltage (I-V) of an extended gate field effect transistor. pH values in solution can be determined from I-V curves at a fixed current.

The invention provides a structure of titanium oxide extended gate field effect transistor (EGFET). The EGFET comprises a metal oxide semiconductor field effect transistor (MOSFET), a sensing device and a conductive wire. The sensing device comprises a substrate and a titanium oxide membrane on the substrate. The MOSFET and the sensing device are connected via the conducting wire.

The invention provides a system of measuring sensitivity of the disclosed titanium oxide EGFET. The system comprises a titanium oxide EGFET, a reference electrode providing a constant voltage, a semiconductor parameter analyzer, a thermal controller and a light isolator. The semiconductor parameter analyzer is connected with the titanium oxide EGFET and the reference electrode. The thermal controller controls temperature of the sensing device and comprises a thermocouple, a heater and temperature controlling unit. The thermocouple and the heater are coupled to the temperature controlling unit. The light isolator protects the sensing device from light radiation. The solution is disposed in the light isolator during pH measurement thereof. The titanium oxide EGFET, the reference electrode and the thermocouple are immersed in the solution. The temperature controlling unit adjusts temperature of the solution, measured by the thermocouple. The detected data of the titanium oxide EGFET and the reference electrode are transmitted to the semiconductor parameter analyzer, which obtains pH values of the solution from I-V curves.

The invention provides a method of measuring sensitivity of the titanium oxide EGFET. The method comprises immersing the titanium oxide membrane of the disclosed titanium oxide EGFET in a solution, varying pH values of the solution at a fixed temperature and recording I-V curves of the titanium oxide EGFET with a semiconductor parameter analyzer, and determining sensitivity of the titanium oxide EGFET at a fixed temperature from the I-V curves.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross section of a conventional ISFET;

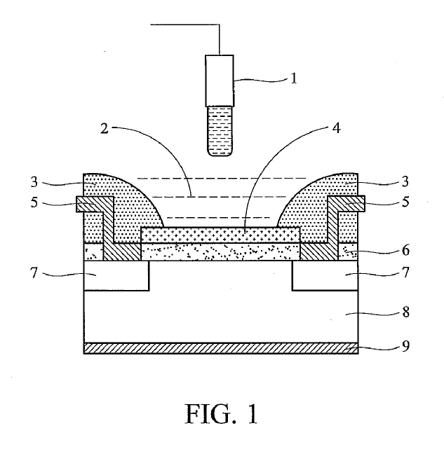

FIG. 2 is a cross section of a titanium oxide extended gate field effect transistor according to an embodiment of the invention;

FIG. 3 is a schematic diagram of a system of measuring I-V curves of the titanium oxide EGFET according to an embodiment of the invention;

FIG. 4 shows I-V curves of a titanium oxide extended gate field effect transistor according to an embodiment of the invention when Ar/O₂ ratio is 10/20;

FIG. 5 shows a relationship between pH value and gate voltage from the curves in FIG. 4.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

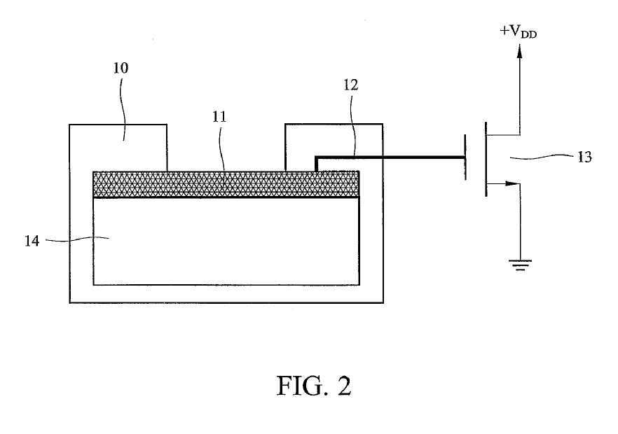

Extended gate field effect transistor (EGFET) is developed from ISFET. A sensing membrane of an EGFET extends from a gate of an ISFET. However, the structure of the metal oxide semiconductor field effect transistor is isolated from the solution, avoiding instability of semiconductor devices and signal interference within the solution. As shown in FIG. 2, a titanium oxide thin film 11 is deposited on a P-type silicon substrate 14 of the EGFET, and the conducting wire 12 is connected to a gate of a MOSFET 13. Preferably, resistivity of the semiconductor substrate ranges from 8-12 Ω-cm and crystal orientation thereof is (1,0,0). In addition, the conducting wire is preferably a aluminum wire. The sensing device is covered by epoxy 10 except part of the titanium oxide membrane 11, which is exposed to the solution. The titanium oxide thin film absorbs hydrogen ions from the solution to generate an electrical signal. The electrical signal controls a channel width of the MOSFET, and concentration of hydrogen ions is obtained from current of the MOSFET.

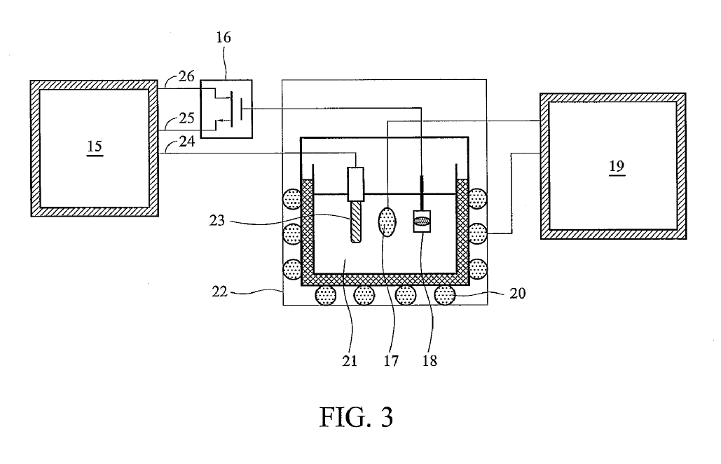

FIG. 3 is a schematic diagram of a system of measuring I-V curves of the titanium oxide EGFET according to an embodiment of the invention. A sensing device 18 of the titanium oxide EGFET is immersed in a buffer solution 21 such as phosphate buffer solution in a container. Source and drain of the sensing device 18 are connected to a semiconductor parameter analyzer 15, such as the Keithley 236, through two conducting wires 25 and 26 such that electrical signals from the MOSFET 16 can be further processed.

A reference electrode 23, such as Ag/AgCl, is immersed in the buffer solution 21 to provide a stable voltage. The reference electrode 23 is also connected to semiconductor parameter analyzer 15 via a conducting wire 24. A set of heaters 20 are disposed outside the container and connected to the temperature controller 19. The temperature controller 19 directs the heaters 20 to adjust temperature of the buffer solution 21. A thermometer 17 connected to the temperature controller 19 detects temperature of the buffer solution 21. The disclosed elements such as the buffer solution 21 and the heater 20 are placed in a light-isolated container 22 to minimize influence of light on measured data.

A method of measuring sensitivity of the titanium oxide EGFET is provided. The method comprises immersing the titanium oxide membrane of the disclosed titanium oxide EGFET in a solution. pH value of the buffer solution is adjusted between pH1 and pH11 at a fixed temperature, typically 25° C. A Semiconductor Parameter Analyzer provides a voltage of 1-6V to the gate of the titanium oxide EGFET, and sets the drain-source voltage at 0.2V. The semiconductor parameter analyzer records curves of drain-source current versus gate voltage of the titanium oxide EGFET. Sensitivity of the titanium oxide EGFET at the fixed temperature is obtained from the curves of drain-source current versus gate voltage.

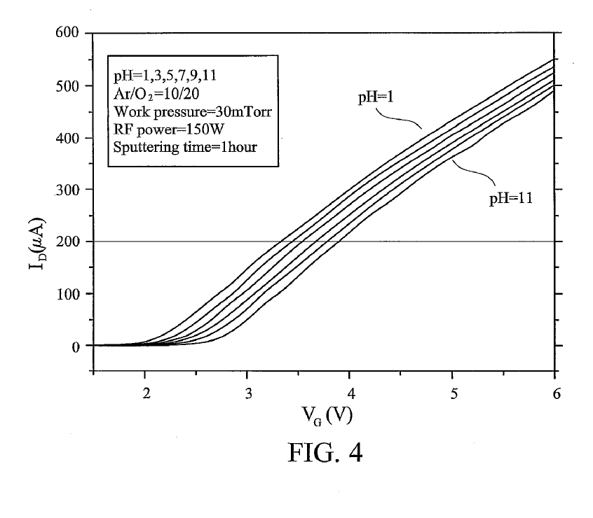

FIG. 4 shows curves of the source-drain current versus gate voltage of the titanium oxide EGFET. The curves shift in parallel with pH value of the buffer solution. This is ascribed to the threshold voltage shift towards a positive value with increasing pH concentration.

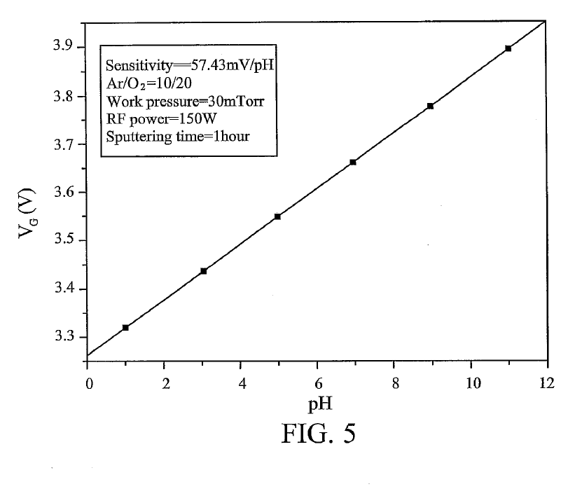

Next, a fixed current (200 μA) of the curve is selected to obtain a curve of gate voltage versus pH value at a fixed temperature (25° C.) as shown in FIG. 5. In FIG. 5, sensitivity of the titanium oxide EGFET at 25° C. is 57.43 mV/pH. It is found that the gate voltage of the titanium oxide EGFET is directly proportional to the pH value of the buffer solution and slope of the curve is the sensitivity of the titanium oxide EGFET at the fixed temperature.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1: A titanium oxide extended gate field effect transistor (EGFET), comprising:
a semiconductor substrate;
a titanium oxide layer on the semiconductor substrate;
a metal wire coupled to the titanium oxide layer;
a seal covering the metal wire and exposing the titanium oxide layer; and
a metal-oxide-semiconductor field effect transistor (MOSFET) having a gate coupled to titanium oxide layer via the metal wire.

2: The titanium oxide EGFET as claimed in claim 1, wherein the semiconductor substrate is a P-type substrate.

3: The titanium oxide EGFET as claimed in claim 1, wherein resistivity of the semiconductor substrate ranges from 8 to 12 Ω-cm.

4: The titanium oxide EGFET as claimed in claim 1, wherein a crystal orientation of the semiconductor substrate is (1,0,0).

5: The titanium oxide EGFET as claimed in claim 1, wherein the metal wire is an aluminum wire.

6: The titanium oxide EGFET as claimed in claim 1, wherein the seal comprises epoxy.

7: The titanium oxide EGFET as claimed in claim 1, wherein the titanium oxide layer is deposited on the semiconductor substrate by reactive sputtering.

8: The titanium oxide EGFET as claimed in claim 1, wherein the reactive sputtering is R.F. sputtering.

9-21. (canceled)
